(19) United States
(12) Patent Application Publication
(10) Pub. No.: US 2012/0003786 A1
(43) Pub. Date: Jan. 5, 2012

(54) ELECTROPLATING METHODS AND CHEMISTRIES FOR CIGS PRECURSOR STACKS WITH CONDUCTIVE SELENIDE BOTTOM LAYER

(76) Inventors: Serdar Aksu, San Jose, CA (US); Mustafa Pinarbasi, Morgan Hill, CA (US)

(21) Appl. No.: 13/184,377

(22) Filed: Jul. 15, 2011

Related U.S. Application Data
(63) Continuation-in-part of application No. 12/642,702, filed on Dec. 18, 2009.
Application No. 12/642,702 is a continuation-in-part of application No. 12/642,709, filed on Dec. 18, 2009.
Application No. 12/642,709 is a continuation-in-part of application No. 12/642,691, filed on Dec. 18, 2009.
Application No. 12/642,691 is a continuation-in-part of application No. 11/952,905, filed on Dec. 7, 2007.

(51) Int. Cl. H01L 31/18

(52) U.S. Cl. 438/95; 257/E31.027

(57) ABSTRACT

The present invention provides a method and precursor structure to form a solar cell absorber layer. The method includes forming a CIGS solar cell absorber on a base by depositing a first layer on the base, where in the first layer includes non-crystalline copper-selenide that is electrically nonconductive, and then heat treating the first layer at a first temperature range to transform the non-crystalline copper-selenide into a crystalline copper-selenide that is electrically conductive, thereby ensuring that the first layer becomes a first conductive layer. Thereafter, other steps follow to complete formation of the CIGS solar cell absorber.

### CROSS REFERENCES TO RELATED APPLICATIONS

This application is a Continuation-in-Part of U.S. patent application Ser. No. 12/642,702, filed on Dec. 18, 2009 entitled “ELECTROPLATING METHODS AND CHEMISTRIES FOR DEPOSITION OF COPPER-INDIUM-GALLIUM CONTAINING THIN FILMS” (SP-101), and this application is a Continuation in Part of U.S. patent application Ser. No. 12/642,709 filed on Dec. 18, 2009 entitled “ENHANCED PLATING CHEMISTRIES AND METHODS FOR PREPARATION OF GROUP IBIIIAVIA THIN FILM SOLAR ABSORBERS” (SP-098), and this application is a Continuation in Part of U.S. patent application Ser. No. 12/642,691 filed on Dec. 18, 2009 entitled “SELENIUM CONTAINING ELECTRO DEPOSITION SOLUTIONS AND METHODS”, (SP-103), and this application is a Continuation in Part of U.S. patent application Ser. No. 11/952,905 filed on Dec. 7, 2007 entitled “ELECTRODEPOSITION TECHNIQUE AND APPARATUS TO FORM SELENIUM CONTAINING LAYERS” (SP-021), all of which are expressly incorporated herein by reference)

### BACKGROUND

1. Field of the Inventions

The present invention relates to manufacturing solar cell absorbers and, more particularly, manufacturing solar cell absorbers using electrodeposition processes.

2. Description of the Related Art

Solar cells are photovoltaic devices that convert sunlight directly into electrical power. The most common solar cell material is silicon, which is in the form of single or polycrystalline wafers. However, the cost of electricity generated using silicon-based solar cells is higher than the cost of electricity generated by the more traditional methods. Therefore, since early 1970's there has been an effort to reduce cost of solar cells for terrestrial use. One way of reducing the cost of solar cells is to develop low-cost thin film growth techniques that can deposit solar-cell-quality absorber materials on large area substrates and to fabricate these devices using high-throughput, low-cost methods.

Group IBIIIAVIA compound semiconductors comprising some of the Group IB (copper (Cu), silver (Ag), gold (Au)), Group IIIA (boron (B), aluminum (Al), gallium (Ga), indium (In), thallium (Tl)) and Group VIA (oxygen (O), sulfur (S), selenium (Se), tellurium (Te), polonium (Po)) materials or elements of the periodic table are excellent absorber materials for thin film solar cell structures. Especially, compounds of Cu, In, Ga, Se and S which are generally referred to as CIGS(S), or Cu(In,Ga)(S,Se)₂ or CuIn₁₋ₓGaₓ (S_{y}Se_{1-y})ₖ , where 0≦x≦1, 0≦y≦1 and k is approximately 2, have already been employed in solar cell structures that yielded conversion efficiencies approaching 20%. Absorbers containing Group IIIA element Al and/or Group VIA element Te also showed promise. Therefore, in summary, compounds containing: i) Cu from Group IB, ii) at least one of In, Ga, and Al from Group IIIA, and iii) at least one of S, Se, and Te from Group VIA, are of great interest for solar cell applications.

The structure of a conventional Group IBIIIAVIA compound photovoltaic cell such as a Cu(In,Ga,Al)(S,Se,Te)₂ thin film solar cell is shown in FIG. 1. The device 10 is fabricated on a base 20 including a substrate 11 and a conductive layer 13. The substrate can be a sheet of glass, a sheet of metal, an insulating foil or web, or a conductive foil or web. The absorber film 12, which includes a material in the family of Cu(In,Ga,Al)(S,Se,Te)₂ , is grown over the conductive layer 13, which is previously deposited on the substrate 11 and which acts as the electrical contact to the device. Various conductive layers comprising molybdenum (Mo), tantalum (Ta), tungsten (W), titanium (Ti), and stainless steel etc. have been used in the solar cell structure of FIG. 1. If the substrate itself is a properly selected conductive material, it is possible not to use a conductive layer 13, since the substrate 11 may then be used as the ohmic contact to the device. After the absorber film 12 is grown, a transparent layer 14 such as a cadmium sulfide (CdS), zinc oxide (ZnO) or CdS/ZnO stack is formed on the absorber film. Radiation 15 enters the device through the transparent layer 14. Metallic grids (not shown) may also be deposited over the transparent layer 14 to reduce the effective series resistance of the device. A variety of materials, deposited by a variety of methods, can be used to provide the various layers of the device shown in FIG. 1. It should be noted that although the chemical formula for a CIGS(S) layer is often written as Cu(In,Ga)(S,Se)₂, a more accurate formula for the compound is Cu(In,Ga)(S,Se)ₖ, where k is typically close to 2 but may not be exactly 2. For simplicity, the value of k will be used as 2. It should be further noted that the notation “Cu(X,Y)” in the chemical formula means all chemical compositions of X and Y from (X=0% and Y=100%) to (X=100% and Y=0%). For example, Cu(In,Ga) means all compositions from CuIn to CuGa. Similarly, Cu(In,Ga)(S,Se)₂ means the whole family of compounds with Ga/(Ga+In) molar ratio varying from 0 to 1, and Se/(Se+S) molar ratio varying from 0 to 1.

The first technique that yielded high-quality Cu(In,Ga)Se₂ films for solar cell fabrication was co-evaporation of Cu, In, Ga and Se onto a heated substrate in a vacuum chamber. Another technique for growing Cu(In,Ga)(S,Se)₂ type compound thin films for solar cell applications is a two-stage process where at least two components of the Cu(In,Ga)(S,Se)₂ material are first deposited onto a substrate, and then reacted with S and/or Se in a high temperature annealing process. For example, for CuInSe₂ growth, thin layers of Cu and In may be first deposited on a substrate and then this stacked precursor layer may be reacted with Se at elevated temperature. If the reaction atmosphere also contains sulfur, then a CuIn(S,Se)₂ layer can be grown. Addition of Ga in the precursor layer, for example use of a Cu/In/Ga stacked film precursor, allows the growth of a Cu(In,Ga)(S,Se)₂ absorber.

Sputtering and evaporation techniques have been used in prior art approaches to deposit the layers containing the Group IB and Group IIIA components of the precursor stacks. In the case of CuInSe₂ growth, for example, Cu and In layers were sequentially sputter-deposited on a substrate and then the stacked film was heated in the presence of a gas containing Se at elevated temperature for times typically longer than about 30 minutes, as described in U.S. Pat. No. 4,798,660. More recently U.S. Pat. No. 6,048,442 disclosed a method comprising sputter-depositing a stacked precursor film comprising a Cu—Ga alloy layer and an In layer to form a Cu—Ga/In stack on a metallic back electrode layer and then reacting this precursor stack film with one of Se and S to form the absorber layer. Such techniques may yield good quality absorber layers and efficient solar cells, however, they suffer from the high cost of capital equipment, and relatively slow rate of production.

One prior art method described in U.S. Pat. No. 4,581,108 utilizes a low cost electrodeposition approach for metallic precursor preparation for a two-stage processing technique. In this method a Cu layer is first electrodeposited on a substrate. This is then followed by electrodeposition of an In layer forming a Cu/In stack during the first stage of the process. In the second stage of the process, the electrodeposited Cu/In stack is heated in a reactive atmosphere containing Se forming a CuInSe₂ compound layer.

In another approach Cu—In or Cu—In—Ga alloys have been electroplated to form metallic precursor layers and then these precursor layers have been reacted with a Group VIA material to form CIGS type semiconductor layers. Some researchers electrodeposited all the components of the Group IBIIIAVIA compound layer. For example, for CIGS film growth electrolytes comprising Cu, In, Ga and Se were used. We will now review some of the work in this field.

Bonnet et al. (U.S. Pat. No. 5,275,714) electroplated Cu—In alloy layers out of acidic electrolytes that contained a suspension of fine Se particles. As described by Bonnet et al., this method yielded an electrodeposited Cu—In alloy layer which contained dispersed selenium particles since during electrodeposition of Cu and In, the Se particles near the surface of the cathode got physically trapped in the growing layer. Lokhande and Hodes (Solar Cells, vol. 21, 1987, p. 215) electroplated Cu-In alloy precursor layers for solar cell applications. Hodes et al. (Thin Solid Films, vol. 128, 1985, p.93) electrodeposited Cu—In alloy films to react them with sulfur to form copper indium sulfide compound layers. They also experimented with an electrolyte containing Cu, In and S to form a Cu—In—S layer. Herrero and Ortega (Solar Energy Materials, vol. 20, 1990, p. 53) produced copper indium sulfide layers through H₂S-sulfidation of electroplated Cu—In films. Kumar et al (Semiconductor Science and Technology, vol. 6, 1991, p. 940, and also Solar Energy Materials and Solar Cells, vol.) formed a Cu—In/Se precursor stack by evaporating Se on top of an electroplated Cu-In film and then further processed the stack by rapid thermal annealing. Prosini et al (Thin Solid Films, vol. 288, 1996, p. 90, and also in Thin Solid Films, vol. 298, 1997, p. 191) electroplated Cu—In alloys out of electrolytes with a pH value of about 3.35-3.5. Ishizaki et al (Materials Transactions, JIM, vol. 40, 1999, p. 867) electroplated Cu-In alloy films and studied the effect of citric acid in the solution. Ganchev et al. (Thin Solid Films, vol. 511-512, 2006, p. 325, and also in Thin Solid Films, vol. 516, 2008, p. 5948) electrodeposited Cu—In—Ga alloy precursor layers out of electrolytes with pH values of around 5 and converted them into CIGS compound films by selenizing in a quartz tube.

Some researchers co-electrodeposited Cu, In and Se to form CIS or CuInSe₂ ternary compound layers. Others attempted to form CIGS or Cu(In,Ga)Se₂ quaternary compound layers by co-electroplating Cu, In, Ga and Se. Gallium addition in the quaternary layers was very challenging in the latter attempts. Singh et al (J. Phys. D: Appl. Phys., vol. 19, 1986, p. 1299) electrodeposited Cu—In—Se and determined that a low pH value of 1 was best for compositional control. Pottier and Maurin (J. Applied Electrochemistry, vol. 19, 1989, p. 361 electroplated Cu—In—Se ternary out of electrolytes with pH values between 1.5 and 4.5. Ganchev and Kochev (Solar Energy Matl. and Solar Cells, vol. 31, 1993, p. 163) carried out Cu—In—Se plating at a maximum pH value of 4.6. Kampman et al (Progress in Photovoltaics, vol. 7, 1999, p. 1999) described a CIS plating method. Other CIS and CIGS electrodeposition efforts include work by Bhattacharya et al (U.S. Pat. Nos. 5,730,852, 5,804,054, 5,871,630, 5,976,614, and 7,297,868), Jost et al (Solar Energy Matl. and Solar Cells, vol. 91, 2007, p. 636) and Kampmann et al (Thin Solid Films, vol. 361-362, 2000, p. 309).

It has been also reported when a two stage process is used, CIGS absorber forms two distinct defect phases during the reaction step because of the varying reaction rate of Se with Ga and In. Such phase separation involving Cu—In—Se (CIS) and Cu—Ga—Se (CGS) phases occurs during the phase formation and nucleation process as the absorber thickness increases. A CGS phase, i.e., Ga-rich region, is generally dominant at the back side of the CIGS layer close to the back contact; whereas, a CIS phase, i.e., an In-rich region, is dominant adjacent the surface of the CIGS layer. These unwanted defect phases degrade and affect the performance of the CIGS, and hence it must be prevented. Therefore, there is a need to develop new methods to deposit CIGS films without defect phases in a repeatable manner with controlled composition.

### SUMMARY OF THE INVENTION

The present invention provides a method and precursor structure to form a solar cell absorber layer.

In one aspect is provided a method to form a solar cell absorber layer. The method includes forming a CIGS solar cell absorber on a base by depositing a first layer on the base, where in the first layer includes non-crystalline copper-selenide that is electrically nonconductive, and then heat treating the first layer at a first temperature range to transform the non-crystalline copper-selenide into a crystalline copper-selenide that is electrically conductive, thereby ensuring that the first layer becomes a first conductive layer. Thereafter, other steps follow to complete formation of the CIGS solar cell absorber.

### BRIEF DESCRIPTION OF THE DRAWING

These and other aspects and features of the present invention will become apparent to those of ordinary skill in the art upon review of the following description of specific embodiments of the invention in conjunction with the accompanying figures, wherein:

FIG. 1 is a schematic view of a prior art solar cell structure;

FIG. 2A is a schematic view of a precursor stack electrodeposited on a base; and

FIG. 2B is a schematic view of a CIGS absorber layer formed when the precursor stack shown in FIG. 2A is reacted.

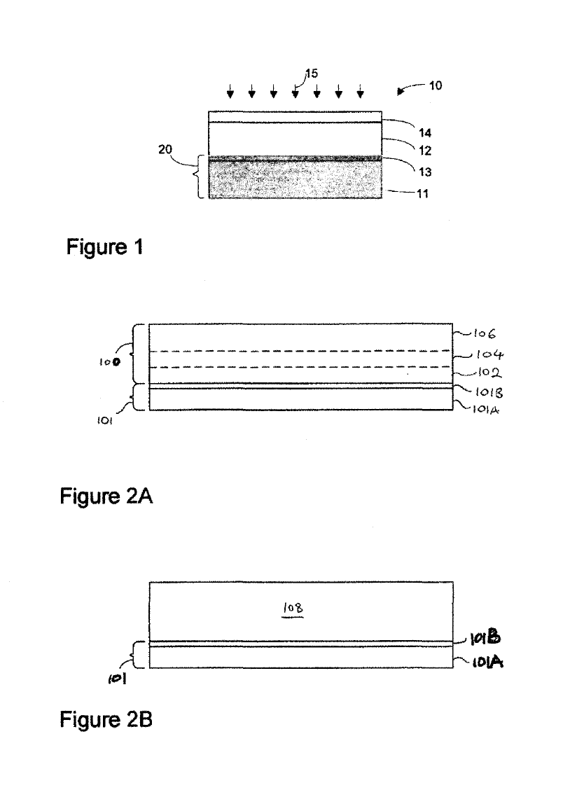

### DETAILED DESCRIPTION OF THE PREFERRED EMBODIMENTS

The present invention provides various methods to form Cu(In, Ga) (Se, S)₂ absorber layers (CIGS) from electrodeposited precursors of the present invention. A precursor of the present invention may be formed as a stack having three layers. A first layer, which is copper poor, may be deposited over a base and a second layer, which is copper rich, deposited onto the first layer. A third layer including selenium is deposited onto the second layer before reacting the precursor to form the CIGS absorber layer. The first layer may include a Group IB-Group IIIA alloy or mixture of stacked films where the Group IB material is preferably Cu and the Group IIIA material is at least one of In and Ga. Such films may include (Cu—In), (Cu—Ga) and (Cu—In—Ga) alloy films or mixture such films. Alternatively, the first layer may include a mixture of stacked single element films, i.e., Cu, In, Ga films, or a mixture of such single element films and (Cu—In), (Cu—Ga) and (Cu—In—Ga) alloy films. The second layer also includes Group IB-Group IIIA alloy or mixture films. Preferably, the second layer may include at least one of a copper-indium-gallium-ternary alloy film, a copper-indium binary alloy film, a copper-gallium binary alloy film and a copper-selenium binary alloy film.

The embodiments, as describe herein, provide methods using electrodeposition solutions or electrolytes to co-electrodeposit uniform, smooth and compositionally repeatable “Group IB-Group IIIA” alloy or mixture films. Of course, the stoichiometry or composition of such films, e.g. Group IB/Group IIIA atomic ratio, may be controlled or varied into desired compositions by varying the appropriate plating conditions to vary the amount of Group IB and Group IIIA or VIA materials in the first layer and the second layer. Through the use of embodiments described herein it is possible to form micron or sub-micron thick alloy or mixture films on conductive contact layer surfaces for the formation of solar cell absorbers.

In another embodiment, the above mentioned separation of CIS and CGS phases due to different selenization rates of Ga and In during CIGS formation may be eliminated by placing a Se layer on top of the precursor stack and also placing one or more metal-selenide layers within the metallic layers of the absorber precursor, i.e., Cu, Ga and In layers, or under such metallic layers. When provided in this configuration, Se is available to react with metals both from the top and bottom of the CIGS precursor. In one implementation, Se is buried under the metallic part of the precursor stack in the form of a copper selenide (Cu—Se) layer. The Cu—Se layer may be electrodeposited, sputter-deposited or evaporation deposited on a back contact layer of a solar cell as a first layer of the CIGS precursor.

FIG. 2A shows an examplary precursor stack 100 or layer formed on a base 101 according to the principles of the present invention. In this embodiment, the precursor stack 100 may be made of a multilayer structure including a first layer 102, a second layer 104 and a third layer 106. The precursor stack 100 is preferably formed using a deposition process. In one implementation using an electrodeposition process, the first layer 102 may be electrodeposited over the base 102 which may include a substrate 101A and a contact layer 101B formed over the substrate. The second layer 104 may also be electrodeposited on the first layer 102 and the third layer 106 may be electrodeposited on the second layer. Principles of the electrodeposition process are well known and will not be repeated here for the sake of clarity. In the next step, the precursor stack 100 is reacted in a reactor to transform it into an absorber layer 108 i.e., CIGS absorber layer, shown in FIG. 2B. The contact layer 101B may be made of a molybdenum (Mo) layer deposited over the substrate 101A or a multiple layers or films of metals stacked on a Mo layer; for example, molybdenum and ruthenium multilayer (Mo/Ru), or molybdenum, ruthenium and copper multilayer (Mo/Ru/Cu). To form a contact layer having multi layers, for example, Ru layer may be electrodeposited on the Mo layer, and similarly the Cu layer may be electrodeposited on the Ru layer to form the contact layer. The substrate 101A may be a flexible substrate, for example a stainless steel foil, or an aluminum foil, or a polymer. The substrate may also be a rigid and transparent substrate such as glass.

As will be described more fully below, the first layer 102 and the second layer 104 of the precursor stack 100 may comprise Group IB and Group IIIA materials, i.e., Cu, In and Ga. In one embodiment the second layer 104 may also include a Group VIA material, such as Se. Accordingly, the first layer 102 may be configured as a stack including a Cu-film, an In-film and a Ga-film, which will be shown with Cu/In/Ga insignia hereinbelow. This and similar insignia will be used throughout the application to depict various stack configurations, where the first material (element or alloy) symbol is the first film, the second material symbol is the second film deposited on the first film and so on. For example, in the Cu/In/Ga stack: the Cu-film, as being the first film of the stack, may be electrodeposited over the contact layer or another stack; the In-film (the second film) is electrodeposited onto the Cu-film; and the Ga-film (the third film) is deposited onto the In-film. In the first layer 102, the order of such films 102 may be changed, and the first layer 102 may be formed as a Ga/Cu/In stack or In/Cu/Ga stack. Furthermore, the first layer 102 may be formed as a stack of four films, such as Cu/Ga/Cu/In or Cu/In/Cu/Ga. In another embodiment, the first layer 102 may be formed as a (Cu—In—Ga) ternary alloy film or as a stack including (Cu—In) binary alloy film and (Cu—Ga) binary alloy film. Such alloy binary or ternary alloy films may have any desired compositions. The first layer 102 may be formed by any possible combinations of the above given stacks of films, binary films and ternary alloy films. Regardless of what combination is used to form it, the first layer 102 includes 35%-49% of the total molar amount of Cu of the precursor stack 100. The rest of the copper, which may be about 51%-65% of the total molar amount of Cu in the precursor layer 100, may be included in the second layer 104. The Cu/(In+Ga) molar ratio for the first layer 102 may be in the range of 0.25 to 0.49.

Referring back to FIG. 2A, the second layer 104 of the precursor stack 100 may include at least one of a (Cu—In—Ga) ternary alloy film, a (Cu—In) binary alloy film and (Cu—Ga) binary alloy film or the mixtures of such films. Alternatively, the second layer 104 may include a (Cu—Se) binary alloy film. The second layer 104 may have a Cu/(In+Ga) molar ratio in the range of 0.51 to 4. In the second layer 104, the amount of copper may be graded vertically between a bottom surface of the second layer 104 (adjacent the top of the first layer 102) and the top surface of the second layer 104 (adjacent the bottom of the third layer 106). When graded, for example, the top portion of the second layer 104 may be made more copper rich than the bottom portion of it. Of course, the bottom portion of the second layer 104 may also be made copper rich with the same approach. The third layer 106 may include Se.

In one example, the first layer 102 may be a Cu/Ga/Cu/In stack, and the second layer 104 may be one of (Cu—In—Ga) ternary alloy film, (Cu—In) binary alloy film, (Cu—Ga) binary alloy film and (Cu—Se) binary alloy film, and the third layer 106 is a selenium layer. In another example, the first layer 102 may be replaced with one of Ga/Cu/In stack, In/Cu/Ga stack and Cu/In/Cu/Ga stack. As mentioned above, in this embodiment, each layer of the precursor stack 100 is electrodeposited from selected electrodeposition solutions or electrolytes. During the process, single element electrolytes, such as a Cu electrolyte, In electrolyte, Ga electrolyte or Se electrolyte, are used to deposit films of these elements. Such electrodeposition solutions includes Cu, In and Ga material sources and complexing agents for each elements. Copper in the electrolyte may be provided by a Cu source such as dissolved Cu metal or a Cu salt such as Cu-sulfate, Cu-chloride, Cu-acetate, Cu-nitrate, and the like. Indium and gallium sources comprise dissolved In and Ga metals, and dissolved In and Ga salts. The In salts may include In-chloride, In-sulfate, In-sulfamate, In-acetate, In-carbonate, In-nitrate, In-phosphate, In-oxide, In-perchlorate, and In-hydroxide, and the like, and wherein the Ga salts may include Ga-chloride, Ga-sulfate, Ga-sulfamate, Ga-acetate, Ga-carbonate, Ga-nitrate, Ga-perchlorate, Ga-phosphate, Ga-oxide, and Ga-hydroxide, and the like. Ethylenediaminetetraacetic acid, tartrate and citrate were selected as suitable complexing agents for Cu, In and Ga, respectively. The pH regime used in the single element electrodeposition solutions is neutral to alkaline pH regime (pH>7). This pH regime was chosen to realize the full potential of the complexation. Deprotonated forms of complexing agents become more predominant with increasing pH, allowing formation of more stable soluble metal-complex species.

For (Cu—In—Ga) ternary alloy film and (Cu—In) or (Cu—Ga) binary alloys films, the preferred electrodeposition solutions comprise a Cu source material, at least one Group IIIA (Ga and In) material, from the above given source materials, and a blend of at least two complexing agents that have the ability to complex with Cu and both or one of the Group IIIA metals to keep them from precipitating in the non-acidic electrolyte which has a pH value of larger than or equal to 7. As is commonly known in the art of electrodeposition, complexing agents are soluble species that combine with metal ions in solution to form soluble complexes or complex ions. It should be noted that the acidic solutions of the prior art techniques may not have used such complexing agents since Group IIIA species typically remain in solution at acidic pH values. In this embodiment, exemplary electrodeposition solutions for (Cu—Ga) binary films preferably comprise citric acid or a citrate, and exemplary electrodeposition solutions for (Cu—In) binary films preferably comprise tartaric acid or a tartrate. Exemplary electrodeposition solutions for (Cu—In—Ga) ternary films preferably comprise a blend of complexing agents including both citrate and tartrate. Using such specific blend of complexing agents at the neutral and high pH ranges improves the plating efficiencies of these Group IB-IIIA materials. Citrates in the blend efficiently complex with the Ga species, tartrates in the blend efficiently complex with the In species. Both tartrates and citrates, on the other hand, complex well with Cu species. In order to enhance the complexation of Cu, EDTA could also be included in the (Cu—In—Ga) electrodeposition solution, because EDTA may form more stable complexes with Cu. Therefore, in electrodeposition solutions comprising Cu and both In and Ga species, it is beneficial to include a blend of complexing agents comprising tartrates (or tartaric acid), citrates (or citric acid) and possibly EDTA (in either its acidic form or in the form of alkali and alkali earth metal salts of EDTA) to obtain high plating efficiencies and good compositional control, i.e. Cu/In, Cu/Ga, In/Ga, Cu/(In+Ga) molar ratios. It should be noted that other complexing agents may additionally be included in the solution formulation.

As mentioned above the electrodeposition solutions or electrolytes used in the embodiments herein preferably have pH values of 7 or higher. A more preferred pH range is above 9. These basic pH values are suitable for large scale manufacturing and provide good complexation for all of the Cu, In and Ga species in the electrolyte and bring their plating potentials close to each other for better repeatability and control of the plated alloy film compositions. It is for this reason that the Ga content of the (Cu—In—Ga) films of the embodiments may be controlled at will in a range from 0% to 100%. This is unlike prior art electrodeposition solutions and methods which generally had difficulty to include appreciable amount of Ga in the electroplated layers due to excessive hydrogen generation due to high negative plating potential of Ga out of acidic electrolytes. It should be noted that the pH values of the prior art plating solutions for the above mentioned group of materials is acidic and less than 7. The embodiments described herein use a neutral (7) to basic (greater than 7) range for the pH values of the electrodeposition solutions and employ at least one complexing agent to effectively complex one of Cu, In and Ga at this pH range. The benefits of such high pH ranges and use of specific complexing agents for the electrodeposition of Ga containing metallic layers (see for example, U.S. patent application Ser. No. 11/535,927, filed Sep. 27, 2006, entitled “Efficient Gallium Thin Film Electroplating Methods and Chemistries”), (In, Ga)-Se containing layers (see for example, U.S. patent application Ser. No. 12/123,372, filed May 19, 2008, entitled “Electroplating Methods and Chemistries for Deposition of Group IIIA-Group VIA thin films”) and Se layers (see for example, U.S. patent application Ser. No. 12/121,687, filed May 15, 2008, entitled “Selenium Electroplating Chemistries and Methods”), each of which are expressly incorporated herein by reference in their entirety.

Although various complexing agents such as tartaric acid, citric acid, acetic acid, malonic acid, malic acid, succinic acid, ethylenediamine (EN), ethylenediaminetetra acetic acid (EDTA), nitrilotriacetic acid (NTA), and hydroxyethylethylenediaminetriacetic acid (HEDTA), etc. may be employed in the electrodepositon solutions for ternary alloy films and higher order material alloy films, the preferred complexing agents are tartaric acid or a tartrate, such as potassium sodium tartrate (KNaC₄H₄O₆) and citric acid or a citrate such as sodium citrate, lithium citrate, ammonium citrate, potassium citrate, and an organically modified citrate.

For Cu—Se, Se material source may comprise at least one of dissolved elemental Se, acids of Se and dissolved Se compounds, wherein the Se compounds include oxides, chlorides, sulfates, sulfides, nitrates, perchlorides and phosphates of Se. Some of the preferred sources include but are not limited to selenous acid (also known as selenious acid) (H₂SeO₃), selenium dioxide (SeO₂), selenic acid (H₂SeO₄), selenium sulfides (Se₄5₄, SeS₂, Se₂5₆) sodium selenite (Na₂SeO₃), telluric acid (H₆TeO₆), tellurium dioxide (TeO₂), selenium sulfides (Se₄5₄, SeS₂, Se₂S₆), ^{thiourea} (CSN₂H₄), and sodium thiosulfate (Na₂S₂O₃).

The preferred complexing agent for the electrolytes used for electroplating Cu—Se binary alloy containing films comprises EDTA, citrates and tartrates. Using such complexing agents, it is possible to prepare plating solutions at both acidic and alkaline regime. An exemplary Cu—Se electrodeposition solution, which operates at low pH regime is provided in SP-103 (CIP of SP-101) and incorporated herein by reference.

In another embodiment, the present invention provides a method to deposit Se containing layers under precursor stacks comprising films of Group IB, Group IIIA and Group VIA materials. As is well known, Ga and In cannot be directly plated on a selenium-containing layer without dissolving a large portion of Se during the electrodeposition. Se dissolves due to its reduction to H₂Se, HSe⁻ or Se²⁻ at the large negative cathodic potentials needed for the deposition of In and Ga. Such undesirable dissolution of Se from the Se-containing layer also occurs during Cu deposition over a Se-containing layer when the plating potential in this process falls below the reduction potential of Se to H₂Se, HSe⁻ or Se²⁻. Se dissolution problem from the Se-containing layer becomes more dramatic if there is a high resistance in the Se-containing layer for passing the desired electrical current during the electrodeposition of next layer. Se dissolution could be minimized or completely eliminated by plating a Cu-rich Cu—Se alloy layer of the present invention and then this layer is covered with a Cu cap layer deposited preferably from an acidic bath. Once a stacking of (Cu—Se)/Cu is formed in this way, other layers can be advantageously electrodeposited on Cu without dissolving the Se in the (Cu—Se) layer. Since molar ratio of Cu in such copper rich Cu—Se layer is more than 50%. The copper cap film, in the thickness range of 100 to 3000 Angstrom is deposited on the (Cu—Se) layer from a low pH (acidic) Cu electrodeposition solution to prevent low reduction potentials in which Se is prone to dissolve in the form of H₂Se or HSe⁻. After depositing the copper cap layer, films of Cu, Ga, and In, or their above described binary or ternary alloy films are electrodeposited on the (Cu—Se)/Cu stack. Absorber layers manufactured from such precursors including Se under other metallic films may improve overall solar cell efficiency. The following film stacks show various examples of precursor stacks including such (Cu—Se)/Cu layering structures, but not limited to: Cu/In/(Cu—Se)/Cu/Ga/Se; Cu/Ga/(Cu—Se)/Cu/In/Cu/In/(Cu—Se)/Cu/In/Se; Cu/In/(Cu—Se)/Cu/Ga/ Cu/In/(Cu—Se)/Cu/In/Se; Cu/Ga/(Cu—Se)/Cu/Ga/Cu/(Cu—In)/(Cu—Se)/Cu/In/(Cu—Se)/Cu/Ga/Se; (Cu—In—Ga)/(Cu—Se)/Cu/Ga/Se; (Cu—Ga)/(Cu—Se)/Cu/In/Se; (Cu—In—Ga)/(Cu—Se)/Cu/Ga/Se; (Cu—Ga)/(Cu—Se)/Cu/In/Se and Cu/In/(Cu—Se)/Cu/Ga/Cu/(Cu—Ga—In)/(Cu—Se)/Cu/In/(Cu—Se)/Cu/Ga/Se.

In another embodiment above mentioned separation of CIS and CGS phases occurring due to different selenization rates of Ga and In metals during CIGS formation may be eliminated by placing a Se layer or a Se containing layer, which is specifically copper-free, on top of the precursor stack and also placing or burying an electrically conductive Se carrying layer, which is a Cu—Se (copper selenide) layer, at the bottom of the precursor stack. In one embodiment of the present invention, an electrically conductive Cu₂Se type copper selenide layer is preferably formed between the contact layer and the metallic part of the precursor stack. Ga and In-rich metallic or metal-selenide layers can be formed between the Cu-free Se containing top layer and the bottom Cu-Se layer. In this configuration Se is available at both ends of the CIGS precursor and may react with metals from the top and bottom, of the CIGS precursor.

Referring to the examplary precursor stack 100 shown in FIG. 2A, for this embodiment, the first layer 102 or the first conductive layer deposited on the base 101 includes the conductive Se carrier layer to introduce selenide into the precursor as the first layer of the precursor. As will be described below the Se carrier layer may be deposited in Se rich or Se poor compositions. Since indium selenide (In—Se) and gallium selenide (Ga—Se) are not electrically conductive, an electrically conductive Cu—Se layer is used as the bottom Se carrier layer so that rest of the precursor stack can be electrodeposited on it. The Cu—Se layer may be deposited on the back contact layer 101B of the solar cell as a first layer of the CIGS precursor stack 100 using various deposition methods including electrodeposition, sputter-deposition or evaporation deposition. It is believed that as deposited Cu—Se layers are often non-crystalline. Such layers may include binary Cu—Se mixtures and compounds as well as unbounded Cu and Se. Due to the variety of stoichiometric and non-stoichiometric copper-selenide forms as well as other pure and mixed phases of Cu and Se, it is often difficult to deposit crystalline, chemically inert and electrically conductive copper selenides at low temperatures. Therefore, when such Cu—Se layers are used as a cathodic base to electrodeposit the subsequent layers, some of the unbounded Se may dissolve from the Cu—Se layer in the subsequent plating processes, causing defects in the CIGS precursor stack and later in the reacted absorber layer.

In one embodiment, such Se loss from the deposited Cu—Se layer may be prevented by obtaining a crystallized Cu—Se layer which stabilizes Se within the crystallized Cu—Se layer and inhibits Se loss during the subsequent electrodeposition steps. As will be described more fully below, in one embodiment, crystallization process of the Cu—Se layer may include an initial regulation of the atomic molar amounts of Cu and Se in the deposited Cu—Se layer, and then subjecting the deposited layer to a heat treatment step to convert the deposited Cu—Se layer into crystalline material structure. This way, an electrically conductive, crystalline and chemically inert Se-containing layer or Se-carrier is formed. The crystalline Cu—Se layer may withstand corrosive electrodeposition environment in the subsequent electrodeposition steps and maintains Se in the crystalline Cu—Se layer.

After forming the first conductive layer 102 as described above, again in this embodiment, the second conductive layer 104 is deposited on the first conductive layer. The second conductive layer 104 may include one or more metallic layers such as Cu, In, and Ga layers or their binary or ternary alloys. After the second conductive layer additional layers including the remaining metallic ingredients or their alloys may be electrodeposited onto the second conductive layer. The third layer 106 or the top layer is deposited onto the second layer or the additional layers and includes the top selenium layer or layers and a NaF layer containing dopant material sodium.

In the next step, the precursor stack 100 is reacted in a reactor to transform it into an absorber layer 108, i.e., CIGS absorber layer, shown in FIG. 2B. The conductive Cu—Se layer forms a conducting base for the electrodeposition of the remaining metals and additional selenium. An examplary precursor stack may include: substrate/back contact/Cu—Se (electrodeposited or sputtered)/ a first Cu-layer/ Ga-layer/a second Cu-layer/In-layer/Se-layer (electroplated)/a NaF layer/Se-layer (evaporated).

As mentioned above, Cu—Se layer may be deposited onto the contact layer 101B using various deposition processes. When an electrodeposition process is used, selenium is a highly soluble element in aqueous solutions, although it is not very conductive electrically. The stability region for un-dissolved solid Se is the largest at low pH values, such as a pH value of less than 4, at relatively high potentials within the range of approximately −0.2 Volts and 0.4 Volts with respect to Standard Hydrogen Electrode (SHE).

In a first implementation of the present invention, Se is incorporated into the bottom of the precursor stack by electrodepositing a Cu-rich Cu-Se layer having a Se amount is in the range of 5-10 atomic percent. When the amount of Cu in Cu—Se layer is higher, the heat treatment step may not be needed because this Cu-rich Cu—Se layer is adequately electrically conductive to perform the next electrodeposition process step, though including it can ensure that any non-crystalline areas will become crystalline and better conductivity results; if carried out it can be performed at high temperatures, preferably in the range of 350-600 ° C., for a duration in the range of 1 to 60 minutes. Over the Cu-rich Cu—Se layer, a Cu layer electrodeposited from preferably an acidic copper-sulfate solution having a pH in the range of 1-3 while applying an electrodeposition potential of −0.1 and 0.4 Volts with respect to SHE. The pH range and electrodeposition potential of the electrodeposition process may be kept within the solid Se stability region.

In a second implementation of the present invention, first, a non-crystalline Cu—Se layer is deposited on the contact layer using electroplating, sputtering or evaporation methods. Next, the Cu—Se layer is then reacted or heat treated at high temperatures to transform it to a crystalline Cu₂Se type Cu—Se layer. The as deposited layer may be made Se-rich and because of the high Se amount, as deposited Cu—Se layer is not conductive. For example, the atomic ratios in the as deposited layer may be regulated so as to deposit a Cu—Se layer that may have an atomic Se/Cu ratio up to about 0.5-1.5, more preferably up to about 1.0 before the heat treatment. As deposited Cu—Se layers including such high amount of Se are also non-crystalline and may contain mixed phases. The subsequent heat treatment step is carried out at high temperatures, preferably in the range of 350-600 ° C. for a duration in the range of 1 to 60 minutes During the heat treatment process, some amount of the Se in the Cu—Se layer reacts with copper to form crystalline Cu—Se while some of it will be lost to the atmosphere as Se easily become volatile at such elevated temperatures. The heat treatment process forms the conductive crystalline Cu—Se layer. Depending on the Se amount in the as-deposited Cu—Se layer and the heat treatment processing conditions, different crystalline phases such as Cu₂₋ₓSe, CuSe, and CuSe₂ may be formed in the Cu—Se layer. The preferred form of crystalline Cu—Se layer is the face-centered-cubic beta phase Cu₂₋ₓSe, where x is in the range of 0 up to approximately 0.3. The commonly observed form of this phase is Cu₂Se with x=0. Heat treatment may be carried out in an O₂-free inert atmosphere containing gases such as nitrogen, argon or helium because presence of oxygen might lead to the formation of unwanted oxide phases. Typical duration of heat treatment may be in the range of 1-60 minutes. After the heat treatment Se/Cu atomic ratio in the crystalline Cu—Se layer may be less than 1. Cu—Se layers may be electrodeposited using Cu-Se electrolytes disclosed in U.S. patent application Ser. No. 12/642,691, entitled: Selenium Containing Electrodeposition Solutions and Methods, filed on Dec. 18, 2009, which is assigned to the assignee of the present application, and which is incorporated herein by reference in its entirety.

As in the previous Cu-rich Cu—Se layer forming process, over the this Cu—Se layer, a Cu layer is again electrodeposited from preferably an acidic copper-sulfate solution having a pH of 1-3 while applying an electrodeposition potential of approximately −0.2 Volts and 0.4 Volts with respect to SHE. It is preferable to put down all the Cu needed for the resultant CIGS layer within the bottom Cu—Se and Cu layers. The rest of the precursor can be formed as described above by electroplating Cu-free layers such as Ga and In metallic layers, In and Ga selenide layers and Se layers. After this NaF and Se can be evaporated to complete the precursor structure for the subsequent CIGS reaction.

Accordingly, an examplary process of the present invention for the preparation of a CIGS precursor stack may include the following: (i) forming a conductive crystalline Cu—Se in the form of Cu₂₋ₓSe (x=0 approximately up to 0.3). at the bottom of the precursor stack by depositing a Cu−Se layer or Cu−Se layers and then heat treating it; (ii) placing all the Cu need in the CIGS layer at the bottom of the precursor in the form of this Cu₂₋ₓSe layer or Cu₂₋ₓSe/Cu layer stack; (iii) plating all the In and Ga needed in the CIGS layer at the top of the Cu-containing layers described in (ii) in the form of metallic or selenide layers; (iv) electrodepositing more Se over the layers described in (iii); (v) evaporating a NaF/Se layer stack on the electrodeposited layer described in (iv) to complete the CIGS precursor stack.

Although the present invention is described with respect to certain preferred embodiments, modifications thereto will be apparent to those skilled in the art.

We claim:

1. A method of forming a CIGS solar cell absorber on a base, comprising:
forming a precursor stack, comprising the steps of:
depositing a first layer on the base, wherein the first layer includes non-crystalline copper-selenide that is electrically nonconductive;
heat treating the first layer at a first temperature range to transform the non-crystalline copper-selenide into a crystalline copper-selenide that is electrically conductive, thereby ensuring that the first layer becomes a first conductive layer;
electrodepositing a second conductive layer onto the first conductive layer after the step of heat treating, wherein the second conductive layer includes at least one of copper, indium and gallium;
electrodepositing a third layer onto the second layer, the third layer including selenium;
depositing a fourth layer onto the third layer, the fourth layer including a dopant element and selenium; and
reacting the precursor stack to form the CIGS absorber layer on the base.

2. The method of claim 1, wherein the step of depositing the first layer includes electrodeposition.

3. The method of claim 1, wherein the crystalline copper selenide includes Cu₂₋ₓSe, where x can range from 0 approximately up to 0.3.

4. The method of claim 3 further comprising, after the step of heat treatment, the step of depositing a copper layer onto the first conductive layer including the crystalline copper selenide.

5. The method of claim 4, wherein the second conductive layer is a stack comprising a layer including gallium electrodeposited onto the first conductive layer and another layer including at least one of indium and an indium/copper stack electrodeposited onto the layer.

6. The method of claim 4, wherein the copper layer is electrodeposited from an electrolyte having a pH of less than 4 while applying a potential in the range of −0.2 to 0.4 with respect to standard hydrogen electrode.

7. The method of claim 1, wherein a Se/Cu atomic ratio of the non-crystalline copper selenide layer is about 1.

8. The method of claim 1, wherein a Se/Cu atomic ratio of the crystalline copper selenide layer is more than 1.

9. The method of claim 1, wherein the temperature range of the heat treatment is 350-600° C., and a duration of the heat treatment has a duration of in the range of 1 to 60 minutes.

10. The method of claim 9, wherein the heat treatment is performed in an oxygen free environment.

11. The method of claim 1, wherein the step of depositing the first layer includes sputter deposition.

12. The method of claim 1, wherein the step of depositing the first layer includes evaporation deposition.

13. The method of claim 1, wherein the step of depositing the fourth layer includes evaporation deposition.

14. A method of forming a CIGS solar cell absorber on a base, comprising:
forming a precursor stack, comprising the steps of:
depositing a first layer on the base, wherein the first layer includes copper-selenide that is no more than partially conductive, such that the entire first layer is no more than partially conductive;
heat treating the first layer at a first temperature range to transform the copper-selenide into a crystalline copper-selenide that is electrically conductive, thereby ensuring that the first layer becomes a first conductive layer;
electrodepositing a second conductive layer onto the first conductive layer after the step of heat treating, wherein the second conductive layer includes at least one of copper, indium and gallium;
electrodepositing a third layer onto the second layer, the third layer including selenium;
depositing a fourth layer onto the third layer, the fourth layer including a dopant element and selenium; and
reacting the precursor stack to form the CIGS absorber layer on the base.

15. The method of claim 14, wherein the step of depositing the first layer includes electrodeposition.

16. The method of claim 14, wherein the crystalline copper selenide includes Cu₂₋ₓSe, where x can range from 0 approximately up to 0.3.

17. The method of claim 16 further comprising, after the step of heat treatment, the step of depositing a copper layer onto the first conductive layer including the crystalline copper selenide.

18. The method of claim 17, wherein the second conductive layer is a stack comprising a layer including gallium electrodeposited onto the first conductive layer and another layer including at least one of indium and an indium/copper stack electrodeposited onto the layer.

19. The method of claim 17, wherein the copper layer is electrodeposited from an electrolyte having a pH of less than 4 while applying a potential in the range of −0.2 to 0.4 with respect to standard hydrogen electrode.

20. The method of claim 14, wherein a Se/Cu atomic ratio of the copper selenide layer is about 1.

21. The method of claim 14, wherein a Se/Cu atomic ratio of the copper selenide layer is more than 1.

22. The method of claim 14, wherein the temperature range of the heat treatment is 350-600° C., and a duration of the heat treatment has a duration of a duration in the range of 1 to 60 minutes.

23. The method of claim 22, wherein the heat treatment is performed in an oxygen free environment.

24. The method of claim 14, wherein the step of depositing the first layer includes sputter deposition.

25. The method of claim 14, wherein the step of depositing the first layer includes evaporation deposition.

26. The method of claim 14, wherein the step of depositing the fourth layer includes evaporation deposition.
